(19) United States
(12) Patent Application Publication
(10) Pub. No.: US 2026/0343762 A1
(43) Pub. Date: Oct. 29, 2026

(54) STANDOFF WITH HOOKS AT OPPOSITE ENDS THEREOF AND AN ELECTRONIC DEVICE INCLUDING THE SAME

(71) Applicant: ABL IP Holding, LLC, Atlanta, GA (US)

(72) Inventors: Sujithlal Thazha, Lilburn, GA (US); Daniel Kim, Snellville, GA (US)

(21) Appl. No.: 19/193,428

(22) Filed: Apr. 29, 2025

(51) Int. Cl. H05K 5/02; H05K 7/18

(52) U.S. Cl. CPC H05K 5/0234; H05K 7/18

(57) ABSTRACT

A standoff for an electronic device. The standoff includes a body, a first hook at a top of the body, and a second hook at the bottom of the body. The first hook and the second hook face in opposite directions. The first and second hooks may each include a base having four corners that each contact an interior surface of a mounting hole for receiving the standoff. The first and second hooks may each include a shank, a bend and an extension defining a gap and a throat. The gap is configured to allow the extension to flex inwardly toward the shank as the standoff passes through a mounting structure hole for receiving the standoff and flex outwardly when the extension passes through the hole.

### FIELD

The present application relates to electronic devices including standoffs, and more particularly, to a standoff with hooks at the opposite ends thereof and an electronic device including the same.

### BACKGROUND

Standoffs are commonly used in manufacture of electronic devices. In general standoffs provide a physical separation between an upper structure, such as a circuit board, and a lower structure. In some applications, standoffs may provide structural support for a circuit board, may protect a circuit board from damage caused by vibrations or shock, may allow for facile positioning of a circuit board during assembly of a device, and/or may ensure proper airflow between a circuit board and the lower structure. Standoffs are sometimes made of materials that are electrically insulating and may thus provide electrical separation between the circuit board and the lower structure to prevent electrical shorts.

A known standoff has a round body and a complex end configuration that requires excessive insertion force for mounting to an upper structure and lower structure, e.g., an insertion pound-force (lbf) of 24 lbf or more. This can cause strain on components mounted to the upper and/or lower structure, causing components thereon to fail. Also, to withstand shock testing, electronic devices with known standoffs may require a sealant, e.g., a silicone room temperature vulcanizing (RTV) sealant, at the interface between the standoff and the upper and lower structures. The sealant increases the material and assembly cost of the electronic device. Known standoff configurations may also be costly to manufacture.

### BRIEF DESCRIPTION OF THE DRAWINGS

FIG. 1 is a side view of one example embodiment of an electronic device including standoffs consistent with the present disclosure.

FIG. 2 is a front view of a standoff shown in FIG. 1.

FIG. 3 is a rear perspective view of the standoff shown in FIG. 2.

FIG. 4 is a right side view of the standoff shown in FIG. 2.

FIG. 5 is a detailed top, front perspective view of a portion of the standoff shown in FIG. 2.

FIG. 6 is a detailed front view of a portion of the standoff shown in FIG. 2.

FIG. 7 is a sectional view of a portion of the electronic device shown in FIG. 1 taken along the length of the standoff shown in FIG. 2.

FIG. 8 is a sectional view of a portion of the electronic device shown in FIG. 1 taken along across the diameter of an upper hole for receiving the standoff shown in FIG. 2.

These and other features of the present embodiments will be understood better by reading the following detailed description, taken together with the figures herein described. The accompanying drawings are not intended to be drawn to scale. In the drawings, each identical or nearly identical component that is illustrated in various figures may be represented by a like numeral. For purposes of clarity, not every component may be labeled in every drawing.

### DETAILED DESCRIPTION

In accordance the present disclosure, there is disclosed a standoff for providing a physical separation between an upper structure and a lower structure. In some embodiments, a standoff consistent with the present disclosure may include a body, a first hook at a top of the body, and a second hook at the bottom of the body. The first hook and the second hook may face in opposite directions. The first and second hooks may each include a base having four corners that each contact an interior surface of an associated mounting hole for receiving the standoff. The first and second hooks may each include a shank, a bend, and an extension defining a gap and a throat. The gap is configured to allow the extension to flex inwardly toward the shank as the standoff passes through an associated mounting hole for receiving the standoff and flex outwardly when the extension passes through the hole.

A standoff consistent with the present disclosure includes several advantageous features. Example embodiments shown and described herein may include all of these these features, and other advantageous features, in combination. It is to be understood, however, that a standoff consistent with the present disclosure may include any one or more of the features described herein, or any combination of two or more of the features described herein. The example embodiments described herein are thus provided by way of illustration, not of limitation.

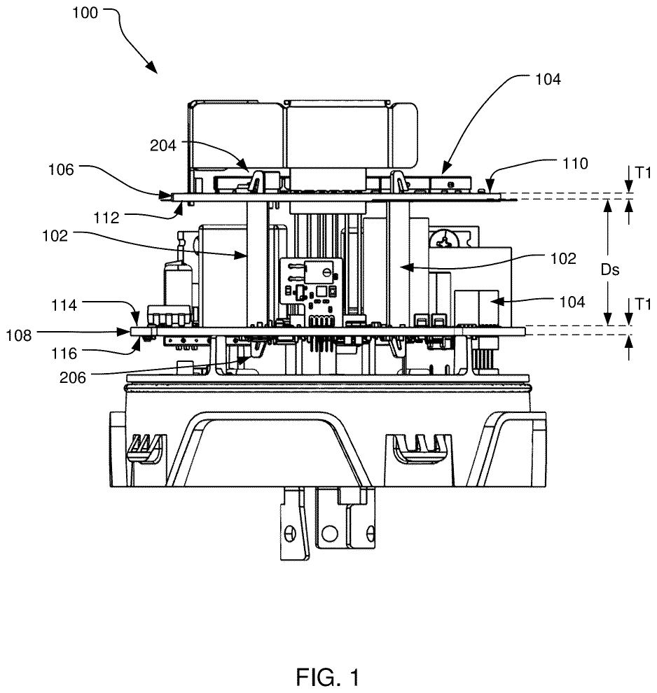

FIG. 1 illustrates one example of an electronic device 100 including two standoffs 102 consistent with the present disclosure. The electronic device 100 may be any device including electronic components 104 operatively coupled for receiving one or more electrical inputs and providing one or more associated outputs in response to the one or more electrical inputs. In the illustrated example embodiment, two standoffs 102 are shown for physically separating the upper structure 106 from the lower structure 108 by a separation distance Ds. Although FIG. 1 shows two standoffs 102 providing separation between an upper structure 106 and a lower structure 108, it is to be understood that an electronic device consistent with the present disclosure may include any number of standoffs 102 and the standoffs 102 may provide physical separation between any number of structures.

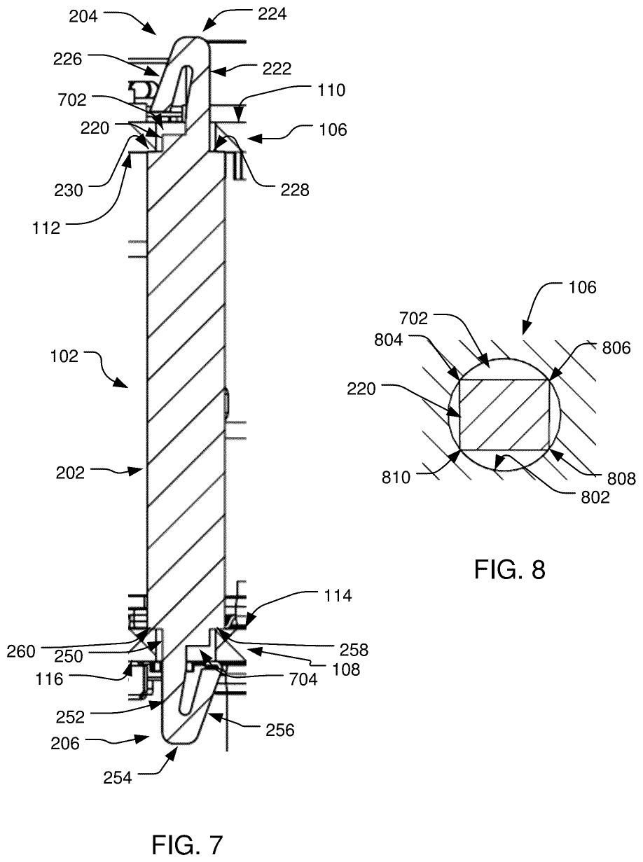

As shown in FIG. 1, both the upper structure 106 and the lower structure 108 may be configured as known planar circuit board structures, e.g., printed circuit boards (PCBs), having a substantially uniform thickness T1. The upper structure 106 has a top surface 110 and a bottom surface 112 with one or more upper mounting holes 702 (FIG. 7) extending therethrough. The top 110 and/or and bottom 112 surfaces and may support electronic components 104 and electrical connections, such as wiring and/or electrical traces, between the electronic components 104. The upper mounting holes 702 are configured to receive the top ends of respective standoffs 102.

The lower structure 108 has a top surface 114 and a bottom surface 116 with one or more lower mounting holes 704 (FIG. 7) extending therethrough. The top 114 and/or and bottom 116 surfaces and may support electronic components 104 and electrical connections, such as wiring and/or electrical traces, between the electronic components 104. The lower mounting holes 704 are substantially axially aligned with associated upper mounting holes 702 and are configured for receiving the bottom ends of respective standoffs 102.

Although the standoffs 102 in the illustrated example embodiment are implemented to provide physical separation for upper 106 and lower 108 structure configured as upper and lower circuit boards, it is to be understood that the upper 106 and lower 108 structures of the electronic device 100 may be provided in a variety of configurations. For example, the upper 106 and/or the lower structure 108 may be configured as a heat sink, an insulating layer, a housing, a mounting tab extending from a circuit board, etc. A standoff 102 consistent with the present disclosure may be configured for providing physical separation of any two components in an electronic device 100. The example embodiments shown herein are thus provided by way of illustration, not of limitation.

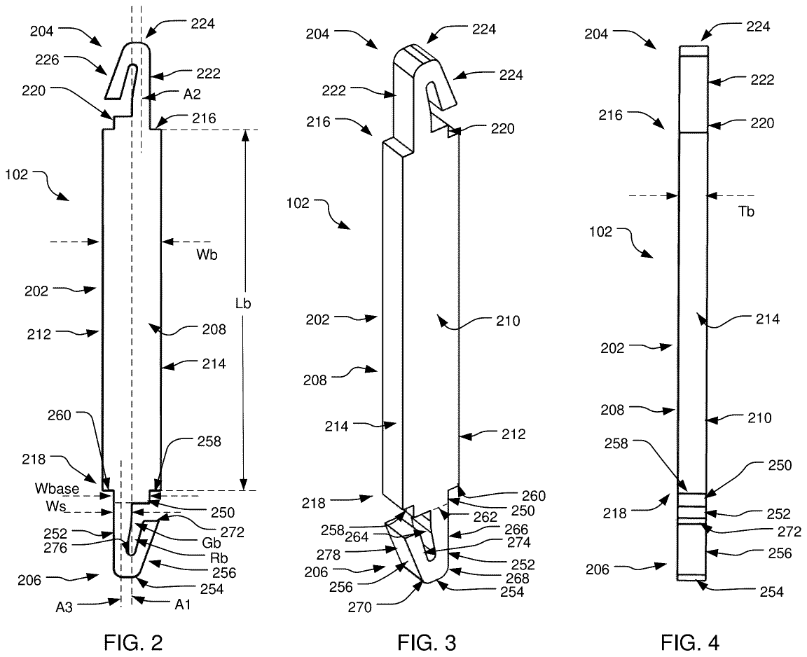

Turning now to FIGS. 2-4, the standoff 102 includes an elongate body 202, a top hook 204, and a bottom hook 206. The standoff 102 has a front 208, a rear 210, and left 212 and right 214 sides, and may be formed from a planar material, such as Nylon 6/6, whereby the body 202, the top hook 204 and the bottom hook 206 are constructed of the same material and have substantially uniform thickness, e.g. as shown in FIG. 4. A cross-section of the standoff 102 taken across the body 202 has a substantially parallelogram shape with the distance from the left side 212 to the right 214 along the front 208 and rear 210 of the body 202 defining a width Wb of the body 202 and a long dimension of the parallelogram-shape, the distance from the front 208 to the rear 210 along the left 212 and right 214 sides of the body 202 defining a thickness Tb of the body 202 and a short dimension of the parallelogram shape. In some embodiments, for example, a standoff 102 consistent with the present disclosure may be cut from planar sheet of material using 2-dimensional (2D) laser cutting or using a punch press.

The body 202 has a top 216 and a bottom 218 and has a length Lb configured to establish the desired physical separation Ds (FIG. 1) between the upper structure 106 and the lower structure 108, as shown in FIG. 1. The top hook 204 extends upwardly from the top 216 of the body 202 and the bottom hook 206 extends downwardly from the bottom 218 of the body 202. In the illustrated example embodiment, the top hook 204 includes a top hook base 220, a top hook shank 222, a top hook bend 224, and a top hook extension 226.

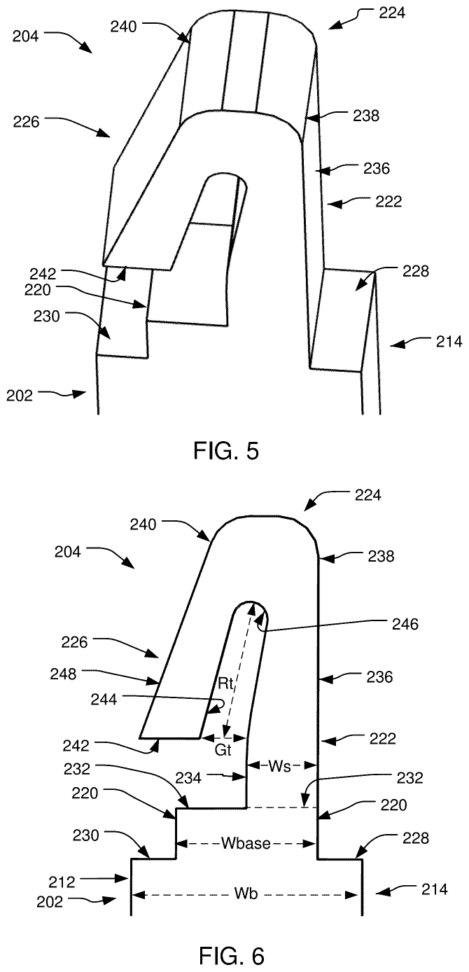

With reference also to FIGS. 5 and 6, the top hook base 220 is a portion of the standoff 102 extending upwardly from the top 216 of the body 202 and having a width Wbase less than the width Wb of the body 202. The top hook base 220 thus defines a first top shelf 228 on the top 216 of the body 202 at the right side 214 of the body 202 and a second top shelf 230 on the top 216 of the body 202 at the left side 212 of the body 202. The top hook base 220 is substantially centered on the top 216 of the body 202, whereby the body 202 and the top hook base 220 share a common longitudinal center axis A1 (FIG. 2) and the first 228 and second 230 top shelves have substantially the same width. In the illustrated example embodiment, the top hook base 220 is substantially rectangular. The top hook base 220 may, however, take other shapes, e.g., square, a truncated triangle, semi-circular, etc.

The top hook shank 222 extends upwardly from a top 232 of the top hook base 220. In the illustrated example embodiment, the top hook shank 222 extends upwardly adjacent the right side of the top hook base 220 so that a longitudinal center axis A2 of the top hook shank 222 is substantially parallel with, and to the right of, the longitudinal center axis A1 of the body 202 and the top hook base 220. The top hook shank 222 has a width Ws less than the width Wbase of the top hook base 220. An inside surface 234 of the top hook shank 222 may be positioned adjacent and to the right of the longitudinal center axis A1 of the body 202 and the top hook base 220, and, in some embodiments, may coincide with the longitudinal center axis A1 of the body 202 and the top hook base 220.

An exterior surface 236 of the top hook shank 222 may extend linearly from a top 232 of the top hook base 220 to an end 238 of the top hook shank 222 where the exterior surface of the top hook 204 begins to curve. The top hook bend 224 extends from the end 238 of the top hook shank 222 and curves downwardly toward the left side 212 of the body 202 to an end 240 of the top hook bend 224.

The top hook extension 226 extends linearly downwardly from the end 240 of the top hook bend 224. The top hook extension 226 has an end surface 242 in a plane positioned above a plane defined by the top 232 of the top hook base 220. The top hook bend 224 establishes a top hook gap Gt between the inside surface 234 of the top hook shank 222 and an interior surface 244 of the top hook extension 226. The top hook bend 224 also establishes a top hook throat Rt between a plane defined by the end surface 242 of the top hook extension 226 and an inside surface 246 surface of the top hook bend 224. Due to the gap Gt and the throat Rt of the top hook 204, when an in inward force applied to an exterior surface 248 of the top hook extension 226, the top hook extension 226 resiliently flexes inwardly toward to top hook shank 222 to close the gap Gt and position the inside surface 244 of the top hook extension 226 adjacent to, or in contact with, the inside surface 234 of the top hook shank 222. When the force is removed, the top hook extension 226 returns to the position shown in FIG. 2-6.

In some embodiments, the bottom hook 206 may be provided in the same, or substantially the same, configuration as the top hook 204. With particular reference again to FIGS. 2-4, the bottom hook 206 includes a bottom hook base 250, a bottom hook shank 252, a bottom hook bend 254, and a bottom hook extension 256.

The bottom hook base 250 is a portion of the standoff 102 extending downwardly from the bottom 218 of the body 202 and having a width Wbase less than a width Wb of the body 202. The bottom hook base 250 thus defines a first bottom shelf 258 on the bottom 218 of the body 202 at the right side 214 of the body 202 and a second bottom shelf 260 on the bottom 218 of the body 202 at a left side 212 of the body 202. The bottom hook base 250 is substantially centered on the bottom 218 of the body 202, whereby the body 202 and the bottom hook base 250 share the longitudinal center axis A1, and the first 258 and second 260 shelves have a substantially similar width. In the illustrated example embodiment, the bottom hook base 250 is substantially rectangular. The bottom hook base 250 may, however, take other shapes, e.g., square, a truncated triangle, semi-circular, etc.

The bottom hook shank 252 extends downwardly from a bottom 262 of the bottom hook base 250. In the illustrated example embodiment, the bottom hook shank 252 extends downwardly adjacent left side of the bottom hook base 250 so that a longitudinal center axis A3 of the bottom hook shank 252 is substantially parallel to, and to the left of, the longitudinal center axis A1 of the body 202 and the bottom hook base 250. The bottom hook shank 252 has a width Ws less than the width Wbase of the bottom hook base 250. An inside surface 264 of the bottom hook shank 252 may be positioned adjacent and to the right of the longitudinal center axis A1 of the body 202 and the bottom hook base 250, and, in some embodiments, may intersect the longitudinal center axis A1.

The bottom hook bend 254 and the bottom hook extension 256 may be configured as described above with respect to the top hook 204, except the bottom hook 206 is in an inverted orientation with respect to the top hook 204 An exterior surface 266 of the bottom hook shank 252 extends linearly downwardly from the bottom 262 of the bottom hook base 250 to an end 268 of the bottom hook shank 252. The bottom hook bend 254 extends from the end 268 of the bottom hook shank 252 and curves upwardly toward the right side 214 of the body 202 to an end 270 of the bottom hook bend 254.

The bottom hook extension 256 extends linearly upwardly from the end 270 of the bottom hook bend 254. The bottom hook extension 256 has an end surface 272 in a plane positioned above a plane defined by the bottom 262 of the bottom hook base 250. As described with respect to the top hook 204, the bottom hook bend 254 establishes a bottom hook gap Gb between the inside surface 264 of the bottom hook shank 252 and an inside surface 274 of the bottom hook extension 256. The bottom hook bend 254 also establishes a bottom hook throat Rb between a plane defined by the end surface 272 of the bottom hook extension 256 and an inside surface 276 of the bottom hook bend 254. Due to the gap Gb and the throat Rb of the bottom hook 206, when an in inward force applied to an exterior surface 278 of the bottom hook extension 256, the bottom hook extension 256 resiliently flexes inwardly toward to bottom hook shank 252 to close the gap Gb and position the inside surface 274 of the bottom hook extension 256 adjacent to, or in contact with, an inside surface 264 of the bottom hook shank 252. When the force is removed, the bottom hook extension 256 returns to the position shown in FIGS. 2-4.

FIG. 7 is a sectional view of a portion of the electronic device 100 of FIG. 1 taken along the length of the standoff 102 shown in FIG. 1. As shown, the upper structure 106 includes the upper mounting hole 702 extending therethrough and the lower structure 108 includes the lower mounting hole 704 therethrough. The upper 702 and lower 704 mounting holes may be configured as standard and known 3 millimeter (mm) diameter, 5 mm diameter, or 7 mm diameter circular mounting holes commonly provided in circuit boards.

When the standoff 102 is installed in the upper structure 106 and the lower structure 108, the top hook 204 is forced into the upper mounting hole 702 from the bottom surface 112 of the upper structure 106 and the bottom hook 206 is forced into the lower mounting hole 704 of the lower structure 108 from a top surface 114 of the lower structure 108. Engagement of the exterior surface 248 of the top hook extension 226 with the interior surface 802 (FIG. 8) of the upper mounting hole 702 forces the top hook extension 226 to resiliently flex inwardly toward the inside surface 234 of the top hook shank 222 to close the gap Gt and position the inside surface 244 of the top hook extension 226 adjacent the inside surface 234 of the top hook shank 222. In this position, the top hook shank 222, top hook bend 224, and top hook extension 226 may extend through the upper mounting hole 702.

When the top hook extension 226 has passed through the upper mounting hole 702, the top hook extension 226 resiliently returns to the position shown in FIGS. 2-7. In this position the bottom surface 242 of the top hook extension 226 is positioned adjacent the top surface 110 of the upper structure 106, the top hook base 220 is disposed in the upper mounting hole 702, and the first 228 and second 230 top shelves are positioned against the bottom surface 112 of the upper structure 106.

Similarly, engagement of the exterior surface 278 of the bottom hook extension 256 with the interior surface of the lower mounting hole 704 forces the bottom hook extension 256 to resiliently flex inwardly toward the inside surface 264 of the bottom hook shank 252 to close the gap Gb and position the inside surface 274 of the bottom hook extension 256 adjacent, or in contact with, the inside surface 264 of the bottom hook shank 252. In this position, the bottom hook shank 252, bottom hook bend 254, and bottom hook extension 256 may extend through the lower mounting hole 704.

When bottom hook extension 256 has passed through the lower mounting hole 704, the bottom hook extension 256 resiliently returns to the position shown in FIGS. 2-4 and FIG. 7. In this position the upper surface 272 of the bottom hook extension 256 is positioned adjacent the bottom surface 116 of the lower structure 108, the bottom hook base 250 is disposed in the lower mounting hole 704, and the first 258 and second 260 bottom shelves are positioned against the upper surface 114 of the lower structure 108. As shown, the top hook 204 and the bottom hook 206 are oriented in opposite directions, which prevents the standoff 102 from inadvertently slipping out of the upper 702 and lower 704 mounting holes, respectively.

Advantageously, the top hook base 220 and the bottom hook base 250 may be configured so that four corners thereof contact the interior surface of the upper 702 and lower 704 mounting holes, respectively. FIG. 8, for example, is a sectional view of a portion of the electronic device 100 shown in FIG. 1 taken across the diameter of upper mounting hole 702. As shown, the top hook base 220 has four corners 804, 806, 808, 810. Each of the corners 804, 806, 808, 810 of the top hook base 220 contacts the interior surface 802 of the upper mounting hole 702. The corners of the bottom hook base 250 may also contact the interior surface of the lower mounting hole 704, as shown in FIG. 8 with respect to the top hook base 220.

In some embodiments, to achieve this configuration in a nylon standoff 102 the standoff 102 should have a thickness Tb (FIG. 4) that allows the standoff 102 to be flexible enough for the top hook 204 and the bottom hook 206 to pass through the upper 702 and lower 704 mounting holes without excessive force that could cause breakage. In some embodiments, for example, when the standoff 102 is to be inserted into a standard 3 mm diameter mounting hole the standoff 102 should have a thickness Tb between about 1.8 millimeters and 2.2 millimeters. In some embodiments, when the standoff 102 is to be inserted into a standard 5 mm diameter mounting hole the standoff 102 should have a thickness Tb between about 3 millimeters and 3.7 millimeters. In some embodiments, when the standoff 102 is to be inserted into a standard 7 mm diameter mounting hole the standoff 102 should have a thickness Tb between about 4.2 millimeters and 5.2 millimeters.

The dimensions of a standoff consistent with the present disclosure may vary depending on the application, and, for example, the configurations of the upper 106 and lower 108 structures, the intended physical separation Ds between the upper 106 and lower 108 structures, the size of the upper 702 and lower 704 mounting holes, the material chosen for the standoff 102, etc. In one example embodiment wherein the upper 702 and lower 704 mounting holes have a standard 3 mm diameter and the standoff 102 is formed of a flat sheet of Nylon 6/6 material, the thickness Tb of the standoff 102 may be about 2 mm, the width Wb of the body may be about 4 mm, the length Lb of the body may be about 25 mm, the width of the base Wbase may be about 2.4 mm, and the width of the shank Ws may be about 1.2 mm.

In some embodiments, a standoff 102 consistent with the present disclosure may be inserted to upper 702 and lower 704 mounting holes of the upper 106 and lower 108 structures, respectively, using an insertion pound-force of less than 3 lbf, which avoids breakage due to excessive force and avoids straining of the upper 106 and lower 108 structures that can cause electrical components thereon, e.g. components 104, to fail. In some embodiments, a standoff 102 consistent with the present disclosure may be inserted to upper 702 and lower 704 mounting holes of the upper 106 and lower 108 structures, respectively, using an insertion pound-force of about 0.7 lbf,

A configuration wherein the corners of the top hook base 220 and the bottom hook base 250 contact the interior surface of the upper mounting hole 702 and the lower mounting hole 704, as shown in FIG. 8, provides stability of the standoff 102 with respect to the upper structure 106 and the lower structure 108. In some embodiments, this configuration allows the electronic device 100 to pass required shock testing. In one embodiment consistent with the present disclosure, for example, an electronic device 100 consistent with this configuration was subjected to a shock test where the electronic device 100 was dropped a 4-foot (ft) height for industrial carpeting and a 3-ft height for concrete to provide impact three times at each of the corners, faces and edges of the electronic device 100. An electronic device 100 consistent with the present disclosure having the corners of the top hook base 220 and the bottom hook base 250 in contact with the interior surface of the upper mounting hole 702 and the lower mounting hole 704, respectively, passed the shock test by exhibiting no physical damage to the electronic device 100 and with the electronic device 100 functioning as intended after the test. Also, a standoff 102 with this configuration did not require any silicone sealing, e.g., silicone room temperature vulcanizing (RTV), at the interface between the standoff 102 and the upper 702 and lower 704 mounting holes, avoiding material and assembly costs associated with applying RTV.

Numerous embodiments will be apparent in light of this disclosure. One example embodiment provides a standoff for providing physical separation between an upper structure and a lower structure in an electronic device. The standoff may include: an elongate body, the body having a top and a bottom; a top hook comprising a top hook base extending upwardly from the top of the body, the top hook base having a width less than a width of the body to define a first top shelf on the top of the body at a first side of the body and a second top shelf on the top of the body at a second side of the body, a top hook shank extending upwardly from a top of the top hook base, the top hook shank having a width less than the width of the top hook base, a top hook bend at the end of the top hook shank, the top hook bend curving downwardly toward the first side of the body, and a top hook extension extending downwardly from the top hook bend, the top hook extension having an end surface positioned above a plane defined by the top of the top hook base, the top hook bend establishing a top hook gap between an inside surface of the top hook shank and an inside surface of the top hook extension and a top hook throat between a plane defined by the end surface of the top hook extension and an inside surface of the top hook bend; and a bottom hook comprising a bottom hook base extending downwardly from the bottom of the body, the bottom hook base having a width less than the width of the body to define a first bottom shelf on the bottom of the body at the first side of the body and a second bottom shelf on the bottom of the body at the second side of the body, a bottom hook shank extending downwardly from a bottom of the bottom hook base, the bottom hook shank having a width less than the width of the bottom hook base, a bottom hook bend at the end of the bottom hook shank, the bottom hook bend curving upwardly toward the second side of the body, and a bottom hook extension extending upwardly from the bottom hook bend, the bottom hook extension having an end surface positioned below a plane defined by the bottom of the bottom hook base, the bottom hook bend establishing a bottom hook gap between an inside surface of the bottom hook shank and an inside surface of the bottom hook extension and a bottom hook throat between a plane defined by the end surface of the bottom hook extension and an inside surface of the bottom hook bend.

According to another aspect of the disclosure there is provided method of providing physical separation between an upper structure and lower structure of an electronic device, the method including: providing a standoff consistent with the present disclosure; inserting the top hook into an upper mounting hole in the upper structure with four corners of the top hook base contacting an interior surface of the upper mounting hole; and inserting the bottom hook into a lower mounting hole in the lower structure with four corners of the bottom hook base contacting an interior surface of the lower mounting hole.

According to another aspect of the present disclosure, there is provided an electronic device including: an upper structure, the upper structure having an upper mounting hole therethrough; a lower structure, the lower structure having a lower mounting hole therethrough; and a standoff. The standoff comprising an elongate body disposed between a bottom surface of the upper structure and a top surface of the lower structure, the body having a top and a bottom, a top hook comprising a top hook base disposed in the upper mounting hole and extending upwardly from the top of the body, the top hook base having a width less than a width of the body to define a first top shelf on the top of the body at a first side of the body and a second top shelf on the top of the body at a second side of the body, the first and second top shelves being positioned adjacent a bottom surface of the upper structure, a top hook shank extending upwardly from a top of the top hook base and through the upper mounting hole, the top hook shank having a width less than the width of the top hook base, a top hook bend at the end of the top hook shank, the top hook bend curving downwardly toward the first side of the body and a top surface of the upper structure, a top hook extension extending downwardly from the top hook bend, the top hook extension having an end surface positioned adjacent the top surface of the upper structure, the top hook bend establishing a top hook gap between an inside surface of the top hook shank and an inside surface of the top hook extension and a top hook throat between a plane defined between the end surface of the top hook extension and an inside surface of the top hook bend, and a bottom hook comprising a bottom hook base disposed in the lower mounting hole and extending downwardly from the bottom of the body, the bottom hook base having a width less than the width of the body to define a first bottom shelf on the bottom of the body at the first side of the body and a second bottom shelf on the bottom of the body at the second side of the body, the first and second bottom shelves being positioned adjacent a top surface of the lower structure, a bottom hook shank extending downwardly from a bottom of the bottom hook base and through the lower mounting hole, the bottom hook shank having a width less than the width of the bottom hook base, a bottom hook bend at the end of the bottom hook shank, the bottom hook bend curving upwardly toward the second side of the body and a bottom surface of the lower structure, and a bottom hook extension extending upwardly from the bottom hook bend, the bottom hook extension having an end surface positioned adjacent the bottom surface of the lower structure, the bottom hook bend establishing a bottom hook gap between an inside surface of the bottom hook shank and an inside surface of the bottom hook extension and a bottom hook throat between a plane defined by the end surface of the bottom hook extension and an inside surface of the bottom hook bend.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future-filed applications claiming priority to this application may claim the disclosed subject matter in a different manner and generally may include any set of one or more limitations as variously disclosed or otherwise demonstrated herein.

It is, therefore, to be understood that the foregoing embodiments are presented by way of example only and that, within the scope of the appended claims and equivalents thereto, the invention may be practiced otherwise than as specifically described and claimed. The present invention is directed to each individual feature, embodiment, system, article, material, kit, and/or method described herein. In addition, any combination of two or more such features, embodiments, systems, articles, materials, kits, and/or methods, if such features, systems, articles, materials, kits, and/or methods are not mutually inconsistent, is included within the scope of the present invention.

The phrase “and/or” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified, unless clearly indicated to the contrary.

The term “coupled” as used herein refers to any connection, coupling, link or the like by which signals carried by one system element are imparted to the “coupled” element. Such “coupled” devices, or signals and devices, are not necessarily directly connected to one another and may be separated by intermediate components or devices that may manipulate or modify such signals. Likewise, the terms “connected” or “coupled” as used herein in regard to mechanical or physical connections or couplings is a relative term and does not require a direct physical connection.

Elements, components, modules, and/or parts thereof that are described and/or otherwise portrayed through the figures to communicate with, be associated with, and/or be based on, something else, may be understood to so communicate, be associated with, and/or be based on in a direct and/or indirect manner, unless otherwise stipulated herein.

Unless otherwise stated, use of the word “substantially” may be construed to include a precise relationship, condition, arrangement, orientation, and/or other characteristic, and deviations thereof as understood by one of ordinary skill in the art, to the extent that such deviations do not materially affect the disclosed methods and systems. Throughout the entirety of the present disclosure, use of the articles “a” and/or “an” and/or “the” to modify a noun may be understood to be used for convenience and to include one, or more than one, of the modified noun, unless otherwise specifically stated. The terms “comprising”, “including” and “having” are intended to be inclusive and mean that there may be additional elements other than the listed elements.

As used herein, use of the term “nominal” or “nominally” when referring to an amount means a designated or theoretical amount that may vary from the actual amount.

Although the terms “first,” “second,” “third” etc. may be used to describe various elements, components, regions, layers and/or sections, these elements, components, regions, layers and/or sections are not to be limited by these terms as they are used only to distinguish one element, component, region, layer or section from another element, component, region, layer or section. Thus, a first element, component, region, layer or section could be termed a second element, component, region, layer or section without departing from the scope and teachings of the present invention.

Although the methods and systems have been described relative to a specific embodiment thereof, they are not so limited. Obviously, many modifications and variations may become apparent in light of the above teachings. Many additional changes in the details, materials, and arrangement of parts, herein described and illustrated, may be made by those skilled in the art.

What is claimed is:

1. A standoff for providing physical separation between an upper structure and a lower structure in an electronic device, the standoff comprising:
an elongate body, the body having a top and a bottom;
a top hook comprising
a top hook base extending upwardly from the top of the body, the top hook base having a width less than a width of the body to define a first top shelf on the top of the body at a first side of the body and a second top shelf on the top of the body at a second side of the body,
a top hook shank extending upwardly from a top of the top hook base, the top hook shank having a width less than the width of the top hook base,
a top hook bend at the end of the top hook shank, the top hook bend curving downwardly toward the first side of the body, and
a top hook extension extending downwardly from the top hook bend, the top hook extension having an end surface positioned above a plane defined by the top of the top hook base, the top hook bend establishing a top hook gap between an inside surface of the top hook shank and an inside surface of the top hook extension and a top hook throat between a plane defined by the end surface of the top hook extension and an inside surface of the top hook bend; and
a bottom hook comprising
a bottom hook base extending downwardly from the bottom of the body, the bottom hook base having a width less than the width of the body to define a first bottom shelf on the bottom of the body at the first side of the body and a second bottom shelf on the bottom of the body at the second side of the body,
a bottom hook shank extending downwardly from a bottom of the bottom hook base, the bottom hook shank having a width less than the width of the bottom hook base, a bottom hook bend at the end of the bottom hook shank, the bottom hook bend curving upwardly toward the second side of the body, and
a bottom hook extension extending upwardly from the bottom hook bend, the bottom hook extension having an end surface positioned below a plane defined by the bottom of the bottom hook base, the bottom hook bend establishing a bottom hook gap between an inside surface of the bottom hook shank and an inside surface of the bottom hook extension and a bottom hook throat between a plane defined by the end surface of the bottom hook extension and an inside surface of the bottom hook bend.

2. The standoff according to claim 1, wherein the top hook base and the bottom hook base each have a cross-sectional shape with four corners and are dimensioned to provide contact between each of the four corners and an interior surface of an upper mounting hole in the upper structure and a lower mounting hole in the lower structure, respectively.

3. The standoff according to claim 1, wherein the standoff has a substantially uniform thickness.

4. The standoff according to claim 1, wherein the standoff has a uniform thickness between about 1.8 millimeters and 2.2 millimeters.

5. The standoff according to claim 1, wherein the standoff has a uniform thickness between about 3 millimeters and 3.7 millimeters.

6. The standoff according to claim 1, wherein the standoff has a uniform thickness between about 4.2 millimeters and 5.2 millimeters.

7. The standoff according to claim 1, wherein the top hook gap is dimensioned to allow the top hook extension to flex inwardly toward the top hook shank when the top hook is inserted upwardly into an upper mounting hole in the upper structure and to flex outwardly when the top hook extension passes through the upper mounting hole, and wherein the bottom hook gap is dimensioned to allow the bottom hook extension to flex inwardly toward the bottom hook shank when the bottom hook is inserted into a lower mounting hole in the lower structure and to flex outwardly when the bottom hook extension passes through the lower mounting hole.

8. A method of providing physical separation between an upper structure and lower structure of an electronic device, the method comprising:
providing a standoff according to claim 1;
inserting the top hook into an upper mounting hole in the upper structure with four corners of the top hook base contacting an interior surface of the upper mounting hole; and
inserting the bottom hook into a lower mounting hole in the lower structure with four corners of the bottom hook base contacting an interior surface of the lower mounting hole.

9. The method according to claim 8, wherein the standoff has a substantially uniform thickness.

10. The method according to claim 8, wherein the standoff has a uniform thickness between about 1.8 millimeters and 2.2 millimeters.

11. The method according to claim 8, wherein the standoff has a uniform thickness between about 3 millimeters and 3.7 millimeters.

12. The method according to claim 8, wherein the standoff has a uniform thickness between about 4.2 millimeters and 5.2 millimeters.

13. The method according to claim 8, wherein the top hook gap is dimensioned to allow the top hook extension to flex inwardly toward the top hook shank when the top hook is inserted upwardly into the upper mounting hole and to flex outwardly when the top hook extension passes through the upper mounting hole, and wherein the bottom hook gap is dimensioned to allow the bottom hook extension to flex inwardly toward the bottom hook shank when the bottom hook is inserted into the lower mounting hole and to flex outwardly when the bottom hook extension passes through the lower mounting hole.

14. An electronic device comprising:
an upper structure, the upper structure having an upper mounting hole therethrough;
a lower structure, the lower structure having a lower mounting hole therethrough; and
a standoff, the standoff comprising
an elongate body disposed between a bottom surface of the upper structure and a top surface of the lower structure, the body having a top and a bottom,
a top hook comprising
a top hook base disposed in the upper mounting hole and extending upwardly from the top of the body, the top hook base having a width less than a width of the body to define a first top shelf on the top of the body at a first side of the body and a second top shelf on the top of the body at a second side of the body, the first and second top shelves being positioned adjacent a bottom surface of the upper structure,
a top hook shank extending upwardly from a top of the top hook base and through the upper mounting hole, the top hook shank having a width less than the width of the top hook base,
a top hook bend at the end of the top hook shank, the top hook bend curving downwardly toward the first side of the body and a top surface of the upper structure, and
a top hook extension extending downwardly from the top hook bend, the top hook extension having an end surface positioned adjacent the top surface of the upper structure, the top hook bend establishing a top hook gap between an inside surface of the top hook shank and an inside surface of the top hook extension and a top hook throat between a plane defined between the end surface of the top hook extension and an inside surface of the top hook bend, and
a bottom hook comprising
a bottom hook base disposed in the lower mounting hole and extending downwardly from the bottom of the body, the bottom hook base having a width less than the width of the body to define a first bottom shelf on the bottom of the body at the first side of the body and a second bottom shelf on the bottom of the body at the second side of the body, the first and second bottom shelves being positioned adjacent a top surface of the lower structure,
a bottom hook shank extending downwardly from a bottom of the bottom hook base and through the lower mounting hole, the bottom hook shank having a width less than the width of the bottom hook base,
a bottom hook bend at the end of the bottom hook shank, the bottom hook bend curving upwardly toward the second side of the body and a bottom surface of the lower structure, and
a bottom hook extension extending upwardly from the bottom hook bend, the bottom hook extension having an end surface positioned adjacent the bottom surface of the lower structure, the bottom hook bend establishing a bottom hook gap between an inside surface of the bottom hook shank and an inside surface of the bottom hook extension and a bottom hook throat between a plane defined by the end surface of the bottom hook extension and an inside surface of the bottom hook bend.

15. The electronic device according to claim 14, wherein the top hook base and the bottom hook base each have a cross-sectional shape with four corners and are dimensioned to provide contact between each of the four corners and an interior surface of the upper mounting hole and the lower mounting hole, respectively.

16. The electronic device according to claim 14, wherein the standoff has a substantially uniform thickness.

17. The electronic device according to claim 14, wherein the standoff has a uniform thickness between about 1.8 millimeters and 2.2 millimeters.

18. The electronic device according to claim 14, wherein the standoff has a uniform thickness between about 3 millimeters and 3.7 millimeters.

19. The electronic device according to claim 14, wherein the standoff has a uniform thickness between about 4.2 millimeters and 5.2 millimeters.

20. The electronic device according to claim 14, wherein the top hook gap is dimensioned to allow the top hook extension to flex inwardly toward the top hook shank when the top hook is inserted upwardly into the upper mounting hole and to flex outwardly when the top hook extension passes through the upper mounting hole, and wherein the bottom hook gap is dimensioned to allow the bottom hook extension to flex inwardly toward the bottom hook shank when the bottom hook is inserted into the lower mounting hole and to flex outwardly when the bottom hook extension passes through the lower mounting hole.
